(19) United States
(12) Patent Application Publication
(10) Pub. No.: US 2017/0160613 A1
(43) Pub. Date: Jun. 8, 2017

(54) TFT SUBSTRATES, TFT TRANSISTORS AND THE MANUFACTURING METHODS THEREOF

(71) Applicant: Shenzhen China Star Optoelectronics Technology Co., Ltd., Shenzhen, Guangdong (CN)

(72) Inventors: Yue WU, Shenzhen, Guangdong (CN); Zhichao ZHOU, Shenzhen, Guangdong (CN)

(73) Assignee: Shenzhen China Star Optoelectronics Technology Co., Ltd., Shenzhen, Guangdong (CN)

(21) Appl. No.: 14/786,123

(22) PCT Filed: Sep. 30, 2015
(86) PCT No.: PCT/CN2015/091283

§ 371 Date: Oct. 21, 2015

(30) Foreign Application Priority Data
Sep. 25, 2015 (CN) 201510621779.3

(51) Int. Cl. G02F 1/1362; G02F 1/1343; H01L 27/12; G02F 1/1368

(52) U.S. Cl. CPC G02F 1/136213; G02F 1/136227; G02F 1/1368; G02F 1/13439; H01L 27/1288; H01L 27/1255; G02F 2201/123; G02F 2202/16; G02F 2203/01

(57) ABSTRACT

A TFT substrate, a TFT transistor and the manufacturing method thereof are disclosed. The method includes: providing a substrate; arranging a gate on the substrate; arranging a semiconductor layer on the gate; arranging a source on the semiconductor layer, and the source electrically connects with the semiconductor layer; and arranging a first insulation layer on the source, and arranging a pixel electrode on the first insulation layer, the pixel electrode operating as a drain electrically connects to the semiconductor layer via a first through hole on the first insulation layer. As such, the short-circuit risk occurring during the etching process of the source and the drain may be reduced when the resistance of the TFT transistor is relatively low.

### BACKGROUND OF THE INVENTION

1. Field of the Invention

The present disclosure relates to liquid crystal display technology, and more particularly to a TFT, a TFT transistor and the manufacturing method thereof.

2. Discussion of the Related Art

Regarding the Thin Film Transistor Liquid Crystal Display (TFT-LCD) technology, alignment of the liquid crystal molecules are controlled by the electrical field generated by an up substrate and a down substrate via TFT transistors. In this way, the optical strength of the transparent pixels are controlled. Usually, TFT transistor includes three electrodes (including a gate, a source and a drain), a gate insulation layer and a semiconductor active layer. During mass production, four or five masks may be adopted in accordance with the component performance, manufacturing process, and the cost.

Currently, one mask is adopted to form the source and drain electrode, and etching solution is adopted for etching the metal. If the distance between the source and the drain is large, the resistance of the TFT transistor may be increased and the charging current may be decreased. If the distance between the source and the drain is small, the short-circuit issue may happen during the wet-etching process.

### SUMMARY

The object of the invention is to provide a TFT substrate, TFT transistors and the manufacturing method thereof. As such, the short-circuit risk occurring during the etching process of the source and the drain may be reduced when the resistance of the TFT transistor is relatively low.

In one aspect, a manufacturing method of TFT transistors includes: providing a substrate; arranging a gate on the substrate; arranging a semiconductor layer on the gate; arranging a source on the semiconductor layer, and the source electrically connects with the semiconductor layer; and arranging a first insulation layer on the source, and arranging a pixel electrode on the first insulation layer, the pixel electrode operating as a drain electrically connects to the semiconductor layer via a first through hole on the first insulation layer.

Wherein the step of arranging the gate on the substrate further includes arranging a first storage electrode on the same layer with the gate on the substrate, and the first storage electrode is spaced apart from the gate.

Wherein the step of arranging the semiconductor layer on the gate further includes arranging a second insulation layer, and a location of second insulation layer corresponding to a portion of the first storage electrode has not been covered by the semiconductor layer.

Wherein the step of arranging the source on the semiconductor layer further includes arranging a second storage electrode in the portion of the second insulation layer that has not been covered by the semiconductor layer such that the second storage electrode is arranged in accordance with the first storage electrode.

Wherein the method further includes: the pixel electrode electrically connects to the second storage electrode via a second through hole on the first insulation layer to charge a storage capacitor formed by the first storage electrode and the second storage electrode.

In another aspect, a TFT transistor includes: a substrate; a gate on the substrate; a semiconductor layer on the gate; a source on the semiconductor layer, and the source electrically connects with the semiconductor layer; a first insulation layer on the source, and a first through hole being arranged in accordance with a location of the semiconductor layer; and a pixel electrode on the first insulation layer, and the pixel electrode operating as a drain electrically connects with the semiconductor layer via the first through hole.

Wherein the TFT transistor further includes a second insulation layer on the gate.

Wherein the TFT transistor further includes: a first storage electrode on the same layer with the gate on the substrate, and the first storage electrode is spaced apart from the gate, wherein a location of second insulation layer corresponding to a portion of the first storage electrode has not been covered by the semiconductor layer; and a second storage electrode is arranged in the portion of the second insulation layer that has not been covered by the semiconductor layer such that the second storage electrode is arranged in accordance with the first storage electrode.

Wherein a second through hole is arranged on the first insulation layer in accordance with a location of the second storage electrode, and the pixel electrode electrically connects with the second storage electrode via the second through hole to charge a storage capacitor formed by the first storage electrode and the second storage electrode.

In another aspect, a TFT substrate includes: a substrate; a gate on the substrate; a semiconductor layer on the gate; a source on the semiconductor layer, and the source electrically connects with the semiconductor layer; a first insulation layer on the source, and a first through hole being arranged in accordance with a location of the semiconductor layer; and a pixel electrode on the first insulation layer, and the pixel electrode operating as a drain electrically connects with the semiconductor layer via the first through hole.

Wherein the TFT transistor further includes a second insulation layer on the gate.

Wherein the TFT substrate further includes: a first storage electrode on the same layer with the gate on the substrate, and the first storage electrode is spaced apart from the gate, wherein a location of second insulation layer corresponding to a portion of the first storage electrode has not been covered by the semiconductor layer; and a second storage electrode is arranged in the portion of the second insulation layer that has not been covered by the semiconductor layer such that the second storage electrode is arranged in accordance with the first storage electrode.

Wherein a second through hole is arranged on the first insulation layer in accordance with a location of the second storage electrode, and the pixel electrode electrically connects with the second storage electrode via the second through hole to charge a storage capacitor formed by the first storage electrode and the second storage electrode.

In view of the above, the method includes: providing a substrate; arranging a gate on the substrate; arranging a semiconductor layer on the gate; arranging a source on the semiconductor layer, and the source electrically connects with the semiconductor layer; and arranging a first insulation layer on the source, and arranging a pixel electrode on the first insulation layer, the pixel electrode operating as a drain electrically connects to the semiconductor layer via a first through hole on the first insulation layer. The source and the drain of the TFT transistor are configured on different layers. As such, the short-circuit issue is avoided even though the distance between the source and the drain is small. Thus, the short-circuit risk occurring during the etching process of the source and the drain may be reduced when the resistance of the TFT transistor is relatively low. In addition, the first insulation layer and the second insulation layer are arranged between the drain and the gate. This increases the distance between the drain and the gate, and thus the parasitic capacitance between the drain and the gate is reduced.

### BRIEF DESCRIPTION OF THE DRAWINGS

FIG. 1 is a flowchart of a manufacturing method of TFT transistors in accordance with one embodiment.

FIG. 2 is a schematic view of the manufacturing method of FIG. 1.

FIG. 3 is a schematic view of the TFT transistor in accordance with one embodiment.

FIG. 4 is a schematic view of the display device in accordance with one embodiment.

### DETAILED DESCRIPTION OF THE EMBODIMENTS

Embodiments of the invention will now be described more fully hereinafter with reference to the accompanying drawings, in which embodiments of the invention are shown.

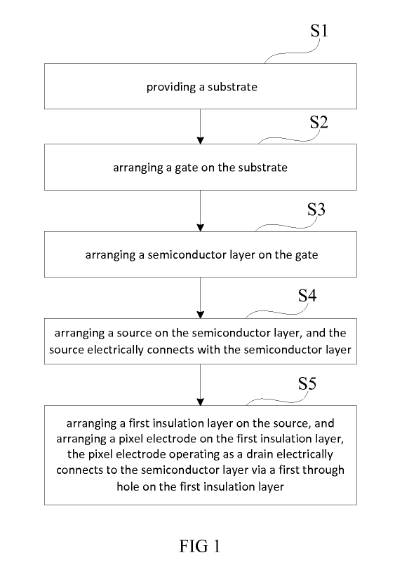

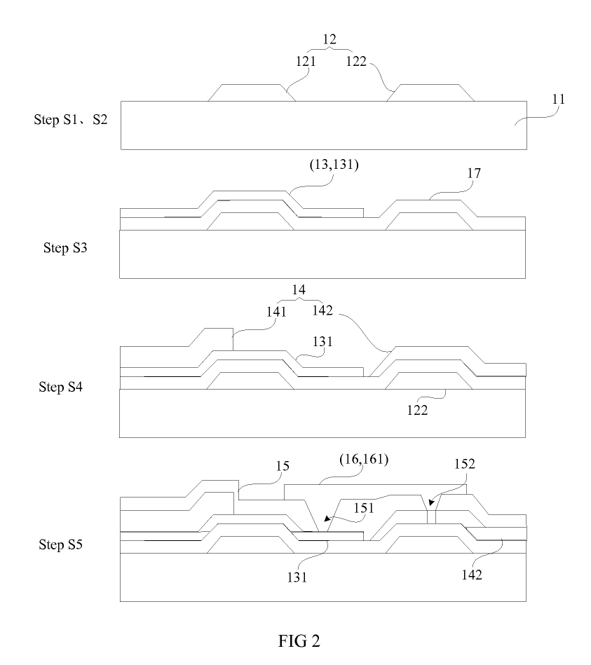

FIG. 1 is a flowchart of a manufacturing method of TFT transistors in accordance with one embodiment. The method includes the following steps.

In block S1, a substrate 11 is provided.

In this step, the substrate 11 may be a glass substrate. Before being provided, the glass substrate is cleaned and dried so as to provide a clean glass substrate.

In block S2, a gate 121 is arranged on the substrate 11.

In this step, a first storage electrode 122 is arranged on the same layer with the gate 121, and the first storage electrode 122 is spaced apart from the gate 121.

Specifically, a metallic layer 12 is deposited via physical vapor deposition (PVD). Afterward, a copy process is applied to the metallic layer 12 so as to patternize the metallic layer 12, and then the gate 121 and the first storage electrode 122 are formed by etching and detachment. In order to save the cost, the above-mentioned etching relates to wet etching.

In block S3, a semiconductor layer 131 is arranged on the gate 121. The semiconductor layer 131 may be made by a-IGZO thin film.

Before this step, a second insulation layer 17 is arranged on the gate 121. Thus, the semiconductor layer 131 is arranged on the second insulation layer 17. Specifically, one IGZO thin film 13 is deposited by PVD, and the copy process, etching, detachment are applied to the IGZO thin film 13 to form the semiconductor layer 131. In order to save the cost, the above-mentioned etching relates to wet etching. The portion of the second insulation layer 17 corresponding to the first storage electrode 122 has not been covered by the semiconductor layer 131.

In block S4, a source 141 electrically connected with the semiconductor layer 131 is arranged on the semiconductor layer 131.

In this step, a second storage electrode 142 is arranged on the portion of the second insulation layer 17 corresponding to the first storage electrode 122 that has not been covered by the semiconductor layer 131. As such, the second storage electrode 142 is configured to be corresponding to the first storage electrode 122 so as to form the storage capacitor.

Specifically, a metallic layer 14 is deposited by the PVD, and the copy process is applied to the metallic layer 14 so as to patternize the metallic layer 14. Afterward, the source 141 and the second storage electrode 142 are formed by etching and detachment. In order to save the cost, the above-mentioned etching relates to wet etching.

In block S5, a first insulation layer 15 is arranged on the source 141, and a pixel electrode 161 is arranged on the first insulation layer 15. The pixel electrode 161 operates as a drain, and electrically connects to the semiconductor layer 131 via a first through hole 151 on the first insulation layer 15. The pixel electrode may be made by Indium tin oxide, (ITO) thin film.

Specifically, the first insulation layer 15 is deposited on the source 141, and the first through hole 151 is formed by applying the copy process, etching, and detachment to the location of the first insulation layer 15 corresponding semiconductor layer 131. Afterward, an ITO thin film 16 is deposited on the first insulation layer 15, and the copy process is applied to patternize the ITO thin film 16. The pixel electrode 161 is formed by etching and detachment. In order to save the cost, the above-mentioned etching relates to wet etching.

It can be understood that as the first through hole 151 is arranged on the first insulation layer 15, when the ITO thin film 16 is deposited on the first insulation layer 15, the ITO thin film 16 located corresponding to the first through hole 151 electrically connects to the semiconductor layer 131 via the first through hole 151.

Further, a second through hole 152 is formed on the first insulation layer 15 in accordance with the location of the second storage electrode 142. The second through hole 152 and the first through hole 151 are formed simultaneously and are formed via the same process. As such, the pixel electrode 161 electrically connect to the second storage electrode 142 via the second through hole 152 so as to charge the storage capacitor formed by the first storage electrode 122 and the second storage electrode 142.

In view of the above, the source 141 and the pixel electrode 161 operating as the drain of the TFT transistor are configured in different layers. As such, the short-circuit issue is avoided even though the distance between the source 141 and the pixel electrode 161 is small. Thus, the short-circuit risk occurring during the etching process of the source and the drain may be reduced when the resistance of the TFT transistor is relatively low.

In addition, the first insulation layer 15 and the second insulation layer 17 are arranged between the pixel electrode 161 operating as the drain and the gate 121. This increases the distance between the pixel electrode 161 and the gate 121, and thus the parasitic capacitance between the drain and the gate is reduced.

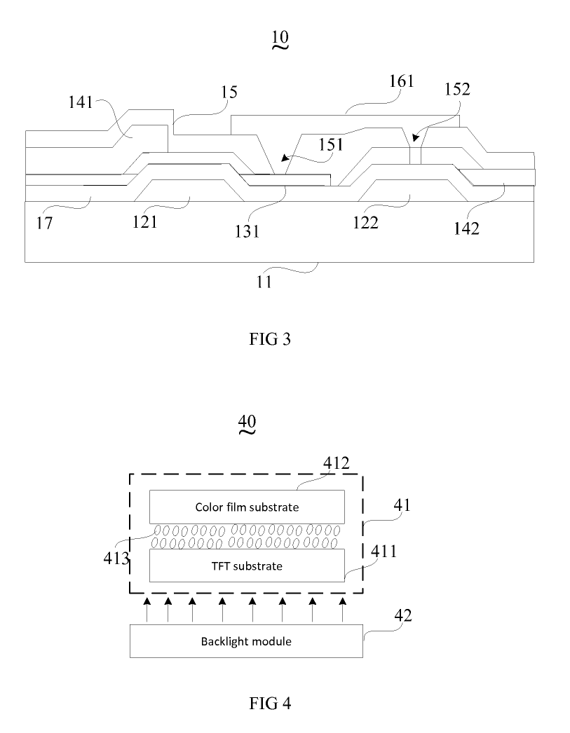

FIG. 3 is a schematic view of the TFT transistor in accordance with one embodiment.

As shown in FIG. 3, the TFT transistor 10 includes a substrate 11, a gate 121, a semiconductor layer 131, a source 141, a first insulation layer 15, and a pixel electrode 161.

The gate 121 is arranged on the substrate 11. The semiconductor layer 131 is arranged on the gate 121. The source 141 is arranged on the semiconductor layer 131 and is connected with the semiconductor layer 131.

The first insulation layer 15 is arranged on the source 141. The first through hole 151 is configured in accordance with the semiconductor layer 131. The pixel electrode 161 is arranged on the first insulation layer 15. The pixel electrode 161 operating as the drain electrically connects with the semiconductor layer 131 via the first through hole 151.

Further, the TFT transistor 10 includes the second insulation layer 17. The second insulation layer 17 is arranged on the gate 121. That is, the semiconductor layer 131 is arranged on the second insulation layer 17.

Further, the TFT transistor 10 includes a first storage electrode 122 and a second storage electrode 142. The first storage electrode 122 is arranged on the substrate 11 and is on the same layer with the gate 121. The first storage electrode 122 is spaced apart from the gate 121. The portion of the second insulation layer 17 corresponding to the first storage electrode 122 has not been covered by the semiconductor layer 131. The second storage electrode 142 is arranged in the portion of the second insulation layer 17 that has not been covered by the semiconductor layer 131. As such, the second storage electrode 142 is arranged in accordance with the first storage electrode 122.

Further, the second through hole 152 is configured on the first insulation layer 15 in accordance with the location of the second storage electrode 142. The pixel electrode 161 electrically connects to the second storage electrode 142 via the second through hole 152 so as to charge the storage capacitor formed by the first storage electrode 122 and the second storage electrode 142.

FIG. 4 is a schematic view of the display device in accordance with one embodiment. As shown, a display device 40 includes a display panel 41 and a backlight module 42 for providing a backlight source to the display panel 41. The display panel 41 further includes a TFT substrate 411, a color film substrate 412 opposite to the TFT substrate 411, and a liquid crystal layer 413 arranged between the TFT substrate 411 and the color film substrate 412. The TFT substrate 411 includes the above-mentioned TFT transistor 10.

In view of the above, the source and the drain of the TFT transistor are configured on different layers. As such, the short-circuit issue is avoided even though the distance between the source and the drain is small. Thus, the short-circuit risk occurring during the etching process of the source and the drain may be reduced when the resistance of the TFT transistor is relatively low.

In addition, the first insulation layer and the second insulation layer are arranged between the drain and the gate. This increases the distance between the drain and the gate, and thus the parasitic capacitance between the drain and the gate is reduced.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A manufacturing method of TFT transistors, comprising:
providing a substrate;
arranging a gate on the substrate;
arranging a semiconductor layer on the gate;
arranging a source on the semiconductor layer, and the source electrically connects with the semiconductor layer; and
arranging a first insulation layer on the source, and arranging a pixel electrode on the first insulation layer, the pixel electrode operating as a drain electrically connects to the semiconductor layer via a first through hole on the first insulation layer.

2. The method as claimed in claim 1, wherein the step of arranging the gate on the substrate further comprises arranging a first storage electrode on the same layer with the gate on the substrate, and the first storage electrode is spaced apart from the gate.

3. The method as claimed in claim 2, wherein the step of arranging the semiconductor layer on the gate further comprises arranging a second insulation layer, and a location of second insulation layer corresponding to a portion of the first storage electrode has not been covered by the semiconductor layer.

4. The method as claimed in claim 3, wherein the step of arranging the source on the semiconductor layer further comprises arranging a second storage electrode in the portion of the second insulation layer that has not been covered by the semiconductor layer such that the second storage electrode is arranged in accordance with the first storage electrode.

5. The method as claimed in claim 4, wherein the method further comprises:
the pixel electrode electrically connects to the second storage electrode via a second through hole on the first insulation layer to charge a storage capacitor formed by the first storage electrode and the second storage electrode.

6. A TFT transistor, comprising:
a substrate;
a gate on the substrate;
a semiconductor layer on the gate;
a source on the semiconductor layer, and the source electrically connects with the semiconductor layer;
a first insulation layer on the source, and a first through hole being arranged in accordance with a location of the semiconductor layer; and
a pixel electrode on the first insulation layer, and the pixel electrode operating as a drain electrically connects with the semiconductor layer via the first through hole.

7. The TFT transistor as claimed in claim 6, wherein the TFT transistor further comprises a second insulation layer on the gate.

8. The TFT transistor as claimed in claim 7, wherein the TFT transistor further comprises:
a first storage electrode on the same layer with the gate on the substrate, and the first storage electrode is spaced apart from the gate, wherein a location of second insulation layer corresponding to a portion of the first storage electrode has not been covered by the semiconductor layer;
a second storage electrode is arranged in the portion of the second insulation layer that has not been covered by the semiconductor layer such that the second storage electrode is arranged in accordance with the first storage electrode.

9. The TFT transistor as claimed in claim 8, wherein a second through hole is arranged on the first insulation layer in accordance with a location of the second storage electrode, and the pixel electrode electrically connects with the second storage electrode via the second through hole to charge a storage capacitor formed by the first storage electrode and the second storage electrode.

10. A TFT substrate, comprising:
a substrate;
a gate on the substrate;
a semiconductor layer on the gate;
a source on the semiconductor layer, and the source electrically connects with the semiconductor layer;
a first insulation layer on the source, and a first through hole being arranged in accordance with a location of the semiconductor layer; and
a pixel electrode on the first insulation layer, and the pixel electrode operating as a drain electrically connects with the semiconductor layer via the first through hole.

11. The TFT substrate as claimed in claim 10, wherein the TFT transistor further comprises a second insulation layer on the gate.

12. The TFT substrate as claimed in claim 11, wherein the TFT substrate further comprises:
a first storage electrode on the same layer with the gate on the substrate, and the first storage electrode is spaced apart from the gate, wherein a location of second insulation layer corresponding to a portion of the first storage electrode has not been covered by the semiconductor layer;
a second storage electrode is arranged in the portion of the second insulation layer that has not been covered by the semiconductor layer such that the second storage electrode is arranged in accordance with the first storage electrode.

13. The TFT substrate as claimed in claim 12, wherein a second through hole is arranged on the first insulation layer in accordance with a location of the second storage electrode, and the pixel electrode electrically connects with the second storage electrode via the second through hole to charge a storage capacitor formed by the first storage electrode and the second storage electrode.
